(19) United States
(12) Patent Application Publication
(10) Pub. No.: US 2016/0303906 A1
(43) Pub. Date: Oct. 20, 2016

(54) TYRE COMPRISING A GRAPHITE OR GRAPHENE COVER FILM DEPOSITED ON AN INNER-LAYER SURFACE

(71) Applicants: Gianluca Forte, Roma (IT); Paolo Fiorenza, Roma (IT); Giuseppe Pezzullo, Roma (IT)

(72) Inventors: Gianluca Forte, Roma (IT); Paolo Fiorenza, Roma (IT); Giuseppe Pezzullo, Roma (IT)

(73) Assignee: BRIDGESTONE CORPORATION, Tokyo (JP)

(21) Appl. No.: 15/101,290

(22) PCT Filed: Dec. 4, 2014
(86) PCT No.: PCT/IB2014/066599

§ 371 Date: Jun. 2, 2016

(30) Foreign Application Priority Data
Dec. 4, 2013 (IT) RM2013A000671

(51) Int. Cl. B60C 1/00; C23C 14/34; C01B 31/04; C23C 14/06

(52) U.S. Cl. CPC B60C 1/0008; C23C 14/0605; C23C 14/34; C01B 31/04; C01B 31/0446; B29D 30/0681

(57) ABSTRACT

A tyre having a rubber inner layer facing the inner cavity of the carcass; and a cover film made entirely of graphite or graphene and deposited on a surface of the inner layer.

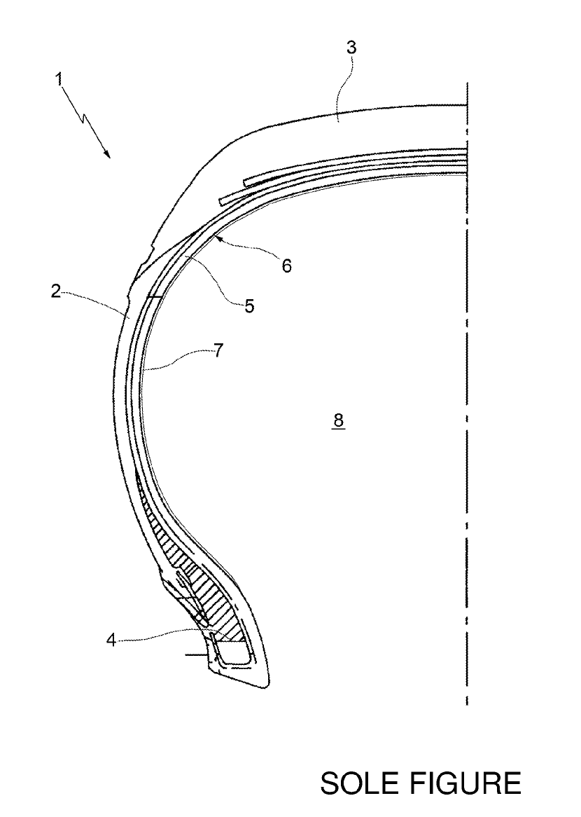

### TECHNICAL FIELD

The present invention relates to a tyre comprising a graphite or graphene cover film on an inner layer.

Here and hereinafter, the term ‘inner layer’ is intended to mean a layer facing the inner cavity of a tubeless tyre carcass; and the term ‘inner-layer inner surface’ to mean the surface of the inner layer facing the inner cavity.

The inner layer normally amounts to the innerliner layer, which is made of rubber substantially impermeable to air and which is used in tyres to maintain the air pressure inside the inner cavity.

The innerliner also serves to confine oxygen, to prevent it from spreading inside the compounds the tyre parts are made of, and so degrading the tyre parts.

One solution to this problem is to increase the thickness of the innerliner to form a better oxygen barrier, but this has the drawback of inevitably increasing both rolling resistance and manufacturing cost.

Innerliner compounds normally have an isobutyl rubber matrix.

### BACKGROUND ART

As is known, the tyre industry needs to produce innerliners that are as thin as possible, but without impairing performance in terms of impermeability. Reducing the thickness of the innerliner mainly has the effect of reducing the weight of the tyre as a whole and therefore rolling resistance.

Patent Applications JP2001-509111 and JP2013-103412 describe the use of a metal film covering the free surface of the innerliner to improve its impermeability properties and so enable a reduction in thickness.

The Applicant has developed a better, alternative solution to those described above.

### DISCLOSURE OF INVENTION

One object of the present invention is a tyre comprising a rubber inner layer facing the inner cavity of the carcass; said tyre being characterized by comprising a cover film made entirely of graphite or graphene and deposited on a surface of said inner layer.

The rubber inner layer need not necessarily be the innerliner, in that the cover film could eliminate the need for a specific impermeable layer such as an innerliner.

Preferably, the inner layer is an innerliner.

Preferably, the cover film is located on an inner surface of the inner layer.

Said cover film is preferably 1 mm thick or less, and more preferably 30 μm thick or less.

A further object of the present invention is use of a cover film made entirely of graphite or graphene and deposited on a surface of a rubber inner layer of a tyre.

### BRIEF DESCRIPTION OF THE DRAWING

For a clearer understanding of the present invention, the following are purely non-limiting examples with the aid of the attached drawing, which shows a partial section of a tyre in accordance with one embodiment of the present invention.

### BEST MODE FOR CARRYING OUT THE INVENTION

### EXAMPLES

A graphite cover film was deposited on a surface of a cured standard innerliner compound specimen.

Table I shows the composition in phr of the innerliner compound.

TABLE I

| | |
|---|---|
| Halobutyl rubber | 100 |
| Carbon black | 50 |
| Clay | 40 |
| Stearic acid | 1 |
| Zinc oxide | 2 |
| Resin | 2.5 |
| Oil | 10 |
| Sulphur | 1 |
| Accelerants | 2 |

The film was deposited using the sputtering technique (SPI Supplies® Module Carbon Coater) and a carbon fibre filament (2 mm thick SPI Supplies® Carbon Fiber), and applying a 6 volt potential difference, with a 0.4 atm deposition chamber pressure. Deposition lasted 10 seconds.

This resulted in an Item A comprising a cured-rubber layer with the composition shown in Table I, and a 20 μm graphite film covering a surface of the cured-rubber layer.

The deposition technique is in no way binding as regards the protective scope of the invention, and may be other than as described above. Item A was aged by applying 7% stretch tension for 5 minutes at 10 Hz frequency.

The resulting aged item is hereinafter referred to as Item B.

Items A and B, together with a control item (Item C), were oxygen impermeability tested at a temperature of 25° C., using a conventional apparatus, such as a MOCON® OX-TRA® (model 2/61).

Control Item C comprises the same cured-rubber layer as Item A, but with no graphite cover film.

Table II shows the impermeability test results indexed with respect to control Item C.

TABLE II

| Item A | Item B | Item C |
|---|---|---|
| 130 | 150 | 100 |

As shown in Table II, the impermeability results of the items in accordance with the present invention are far superior to that of the control item, which would suggest that an innerliner produced in accordance with the present invention is capable of ensuring greater impermeability than a standard innerliner represented by control Item C.

More specifically, the Item B results show the advantages in terms of oxygen impermeability of the innerliner according to the present invention are preserved even after prolonged use.

Number 1 in the attached drawing indicates a tyre as a whole. Tyre 1 comprises a carcass 2, a tread 3, and a bead 4. Carcass 2 comprises an innerliner 5. And a graphite or graphene cover film is deposited on the inner surface 6 of innerliner 5 facing the inner cavity 8 of the carcass.

Enhancing impermeability with the graphite or graphene cover film allows the innerliner to be made thinner, with all the advantages this affords in terms of weight and, therefore, rolling resistance.

Compared with the metal-film-coated innerliner solution, the graphite or graphene film in the present invention has the advantages of improving thermal stability, chemical resistance, and rubber compatibility. Moreover, compared with metal films in the known solution, the graphite or graphene film also has the advantages of being more environment-friendly, and being achievable using potentially simpler deposition techniques.

1. A tyre comprising a rubber inner layer facing the inner cavity of the carcass; said tyre comprising a cover film made entirely of graphite or graphene and deposited on a surface of said inner layer.

2. A tyre as claimed in claim 1, wherein the inner layer is an innerliner.

3. A tyre as claimed in claim 1, wherein said cover film is located on an inner surface of the inner layer.

4. A tyre as claimed in claim 1, wherein said cover film is 1 mm thick or less.

5. A tyre as claimed in claim 1, wherein said cover film is 30 μm thick or less.

6. Use of a cover film made entirely of graphite or graphene and deposited on a surface of a rubber inner layer of a tyre.
